(19) United States
(12) Patent Application Publication
(10) Pub. No.: US 2012/0300413 A1
(43) Pub. Date: Nov. 29, 2012

(54) POWER FEEDING DEVICE FOR ELECTRONIC CASSETTE

(75) Inventor: Tomoyuki IIDA, Kanagawa (JP)

(73) Assignee: FUJIFILM CORPORATION, Tokyo (JP)

(21) Appl. No.: 13/480,115

(22) Filed: May 24, 2012

(30) Foreign Application Priority Data
May 24, 2011 (JP) 2011-115882

(51) Int. Cl. H05K 7/00

(52) U.S. Cl. 361/728

(57) ABSTRACT

An imaging support has a power feeding device that carries out a noncontact power feeding operation in an electromagnetic induction method. When a cassette is loaded in a cassette chamber of the imaging support, a power feeding controller of the power feeding device issues a query signal. In a case where the cassette loaded in the cassette chamber is an electronic cassette having a noncontact power receiving function, this electronic cassette issues a response signal answering the query signal. Upon receiving the response signal, the power feeding controller judges that the cassette is the electronic cassette, and starts the noncontact power feeding operation. On the other hand, in a case where the cassette loaded in the cassette chamber does not have the noncontact power receiving function, no response signal is issued. The power feeding controller stops issuing the query signal after a lapse of predetermined time.

### BACKGROUND OF THE INVENTION

1. Field of the Invention

The present invention relates to a power feeding device for charging power to an electronic cassette that is set in a radiation imaging apparatus.

2. Description Related to the Prior Art

In medical diagnosis and treatment, a radiographic image capturing system, for example, an X-ray image capturing system is widely used. The X-ray image capturing system is constituted of an X-ray generating apparatus having an X-ray source, and an X-ray imaging apparatus having an electronic cassette. The electronic cassette is composed of a flat panel detector (FPD) and a flat rectangular housing containing the FPD. The FPD has a matrix of pixels each of which accumulates signal charge by an amount corresponding to the amount of X-rays incident thereon. The FPD accumulates the signal charge on a pixel-by-pixel basis, and converts the accumulated signal charge into a voltage signal in its signal processing circuit. Thereby, the FPD electrically detects an X-ray image, and outputs the X-ray image as digital image data.

The electronic cassette is set not only in a specific imaging support, but also in an existing imaging support shareable among a film cassette, an IP cassette, and a CR cassette. Furthermore, the electronic cassette can be used while being put on a bed or held by a patient himself/herself, when taking a radiograph of a body part that is hard to take with a stationary detector. The electronic cassette is sometimes brought out from a hospital for use in bedside radiography of a home-care patient or to the outside for use in an accident or natural disaster site in an emergency.

There is a type of electronic cassette that has a built-in battery for supplying drive power to its internal components and a wireless communicator for establishing communication with an external control device by radio. In recharging such a type of electronic cassette, the battery is pulled out of the electronic cassette and set on a specific charging cradle. In another case, the electronic cassette itself may be set on a charging cradle to charge the battery in the state of being contained in the electronic cassette.

Also, there is proposed a radiographic image capturing system in which a noncontact power feeding device adopting an electromagnetic induction method or a magnetic resonance method is disposed in the vicinity of the X-ray imaging apparatus. The noncontact power feeding device can charge power to the battery built into the electronic cassette that is set in the X-ray imaging apparatus (refer to US Patent Application Publication No. 2010/0243910 corresponding to Japanese Patent Laid-Open Publication No. 2010-250292). In this system, the taking of radiographs is forbidden during a noncontact power feeding operation, to prevent deterioration of image quality by superimposition of noise caused by the power feeding operation on the radiographs. The power feeding device forms a weak magnetic field to detect whether or not the electronic cassette exists in a charging area.

In an actual medical site, various types of cassettes, including the electronic cassette with a power receiving function and cassettes without having the power receiving function (an electronic cassette, an IP cassette, and a CR cassette of various manufacturers without having the power receiving function), are loadable onto a common imaging support. For this reason, in the case of providing the power feeding device for charging the built-in battery of the electronic cassette on or in the vicinity of the imaging support, consideration must be given such that the power feeding device does not affect the use of the cassette without having the power receiving function.

In the system of the US Patent Application Publication No. 2010/0243910 in which the power feeding device forms the weak magnetic field to search for the electronic cassette, the cassette without having the power receiving function cannot respond to the magnetic field, so the power feeding device keeps applying a magnetic flux. When the radiographs are taken or radiograph data is transmitted to the external control device in this state, noise caused by the magnetic field deteriorates image quality. If the image quality deterioration is severe, the radiographs have to be taken again, and extra time and effort are required. Furthermore, the patient has to be exposed to an extra dose.

Especially, the electronic cassette uses the FPD that is sensitive enough to detect a feeble electromagnetic wave, with the aim of reducing exposure of the patient to the radiation. Thus, in the case of using the electronic cassette without having the power receiving function, the magnetic field applied by the power feeding device could be noise and cause image unevenness of a non-negligible level. Also, in the CR cassette, the magnetic field could affect the movement of molecules of a phosphor by Lorentz force.

### SUMMARY OF THE INVENTION

An object of the present invention is to provide a power feeding device for an electronic cassette in which an electronic cassette searching operation does not cause image deterioration.

A power feeding device according to the present invention includes a signal sending section, a signal receiving section, and a control section. The signal sending section sends a query signal as a query operation to check whether or not a cassette being set in a predetermined position is an electronic cassette having a power receiving function. The signal receiving section receives a response signal issued by the electronic cassette in response to the query signal. The control section starts the query operation, and stops the query operation, in a case where no response signal is received for a predetermined time. The control section enables a noncontact power feeding operation to a battery, in a case where the set cassette is judged to be the electronic cassette having the power receiving function by a reception of the response signal.

If the cassette is set in the predetermined position, the cassette is loaded in a cassette chamber formed in an imaging support. The signal sending section and the signal receiving section are preferably provided in the imaging support. Each of the signal sending section and the signal receiving section preferably includes an antenna for sending and receiving an electromagnetic wave. The signal sending section and the signal receiving section preferably carry out the noncontact power feeding operation to the battery, in addition to the query operation. A weak electromagnetic wave is preferably used in the query operation, while a strong electromagnetic wave is preferably used in the noncontact power feeding operation.

The power feeding device may further include a cassette detector for detecting loading of the cassette in the cassette chamber. When the cassette detector detects the loading of the cassette, the control section may start the query operation. In another case, upon turning on of the cassette, the control section may start the query operation.

The power feeding device may further include a nonvolatile memory for storing information about whether or not the electronic cassette has the power receiving function, which is judged by presence or absence of the reception of the response signal. At this time, the cassette detector is maintained in an energized state, even after the imaging support is turned off. In a case where the cassette detector detects replacement of the cassette during turn-off of the imaging support, the control section carries out the query operation upon turn-on of the imaging support. In a case where the cassette detector does not detect replacement of the cassette during turn-off of the imaging support, the control section does not carry out the query operation upon turn-on of the imaging support, and based on the information stored on the nonvolatile memory, the control section enables the noncontact power feeding operation if the cassette is the electronic cassette. The nonvolatile memory is preferably provided in an imaging control device, which is connected to the imaging support and controls operation of the electronic cassette.

The control section preferably stops the noncontact power feeding operation, while the electronic cassette is in process of taking a radiograph or transmitting data of the radiograph. Furthermore, the control section preferably stops the noncontact power feeding operation, in a case where the battery is in a full charge state or a case where the electronic cassette is unloaded from the cassette chamber.

According to the present invention, the issue of the query signal for searching for the electronic cassette having the noncontact power receiving function is stopped after a lapse of predetermined time. Therefore, even if the cassette without having the power receiving function is used, it is possible to prevent the occurrence of deterioration in image quality caused by the query signal.

### BRIEF DESCRIPTION OF THE DRAWINGS

For more complete understanding of the present invention, and the advantage thereof, reference is now made to the following descriptions taken in conjunction with the accompanying drawings, in which:

FIG. 1 is a schematic view showing the structure of an X-ray image capturing system;

FIG. 2 is a perspective view of an electronic cassette;

FIG. 3 is a schematic circuit diagram of the electronic cassette and an FPD;

FIG. 4 is a block diagram of a power feeding device and a power receiving function of the electronic cassette;

FIG. 5 is a flowchart of an electronic cassette searching procedure;

FIG. 6 is a flowchart in a used state of the electronic cassette; and

FIG. 7 is a block diagram of a power feeding device having a nonvolatile memory.

### DESCRIPTION OF THE PREFERRED EMBODIMENTS

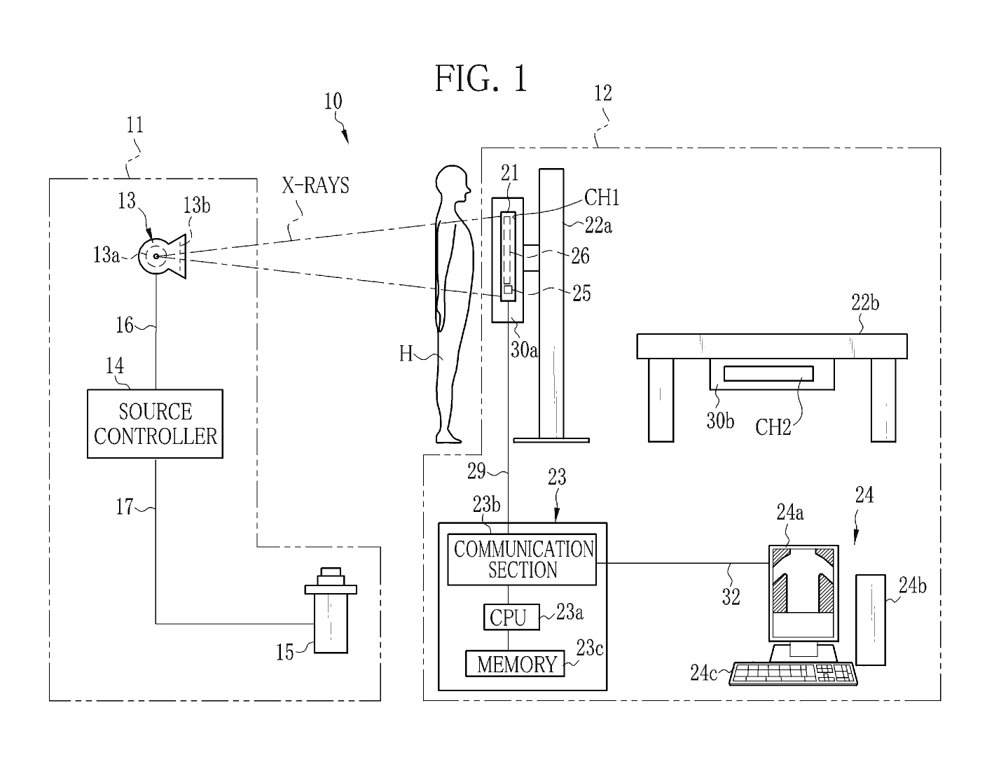

As shown in FIG. 1, an X-ray image capturing system 10 is constituted of an X-ray generating apparatus 11 and an X-ray imaging apparatus 12. The X-ray generating apparatus 11 includes an X-ray source 13, a source controller 14 for controlling operation of the X-ray source 13, and an exposure switch 15. The X-ray source 13 has an X-ray tube 13a for emitting X-rays, and a collimator 13b for limiting an irradiation field of the X-rays emitted from the X-ray tube 13a.

The X-ray tube 13a has a cathode being a filament for emitting thermoelectrons, and an anode (target) for radiating the X-rays by collision of the thermoelectrons emitted from the cathode. The target is a disk-shaped rotating anode in which rotation moves focus of the collision with the thermoelectrons in circumferential orbit to disperse heat production from the focus. The collimator 13b is composed of four X-ray shielding lead plates disposed on each side of a rectangle so as to form an irradiation opening in its middle through which the X-rays propagate. Changing the positions of the lead plates can vary the size of the irradiation opening to limit the irradiation field.

The source controller 14 includes a high voltage generator and a controller (neither is shown). The high voltage generator supplies high voltage to the X-ray source 13. The controller controls a tube voltage for determining an energy spectrum of the X-rays from the X-ray source 13, a tube current for determining an X-ray irradiation amount per unit of time, and an X-ray irradiation duration. The high voltage generator produces the high tube voltage by multiplying an input voltage using a transformer, and supplies drive power to the X-ray source 13 through a high voltage cable 16. The X-ray generating apparatus 11 according to this embodiment has no function of communicating with the X-ray imaging apparatus 12. Thus, image capturing conditions including the tube voltage, the tube current, and the X-ray irradiation duration are set up manually by a doctor or a radiologic technologist from an operation panel of the source controller 14.

The exposure switch 15, which is operated by the doctor or the radiologic technologist, is connected to the source controller 14 through a signal cable 17. The exposure switch 15 is a two-step switch. Upon a half press of the exposure switch 15, a warm-up start signal is issued to start warming up the X-ray source 13. Upon a full press of the exposure switch 15, an irradiation start signal is issued to make the X-ray source 13 start emitting the X-rays. These control signals are inputted to the source controller 14 through the signal cable 17.

The source controller 14 controls the operation of the X-ray source 13 based on the control signals from the exposure switch 15. Upon reception of the warm-up start signal, the source controller 14 preheats the filament by actuating a heater, and starts rotating the target and accelerates it to a predetermined rotation speed. The time required for warming up is of the order of approximately 200 msec to 1500 msec. The doctor or the radiologic technologist inputs the warm-up start signal by the half press of the exposure switch 15, and then inputs the irradiation start signal by the full press of the exposure switch 15 after a lapse of time required for the warming up.

Upon reception of the irradiation start signal, the source controller 14 starts supplying electric power to the X-ray source 13, and, at the same time, actuates a timer to start measuring the X-ray irradiation duration. After a lapse of the predetermined X-ray irradiation duration set up by the image capturing conditions, the source controller 14 stops application of the X-rays. The X-ray irradiation duration depends on the image capturing conditions. In taking a static image, the X-ray irradiation duration is generally set at the order of approximately 500 msec to 2 sec at the maximum. The X-ray irradiation duration is limited to this maximum.

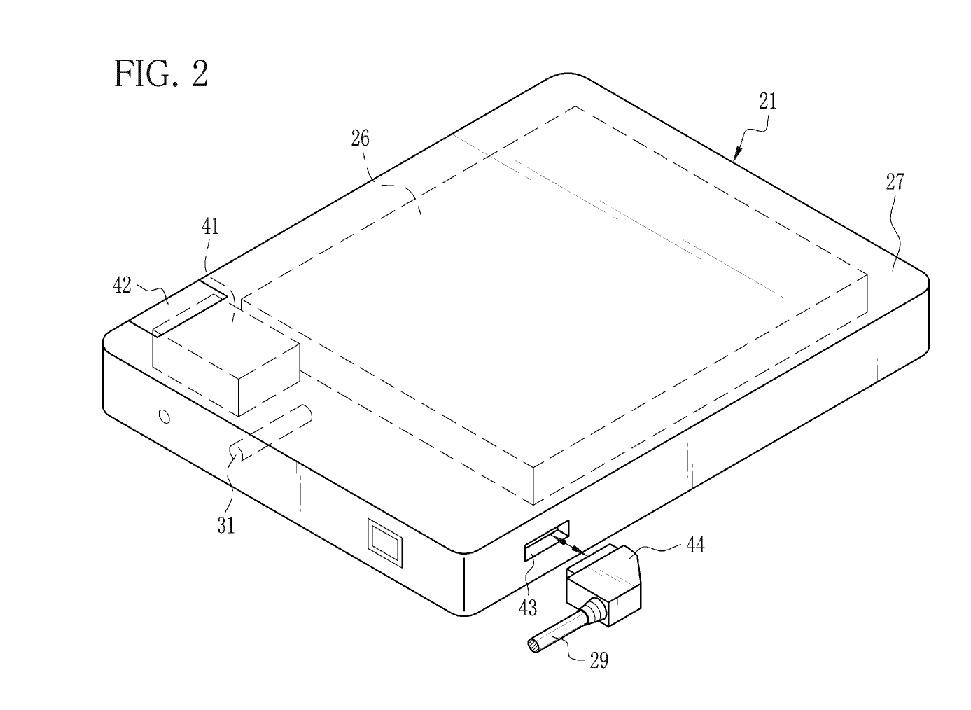

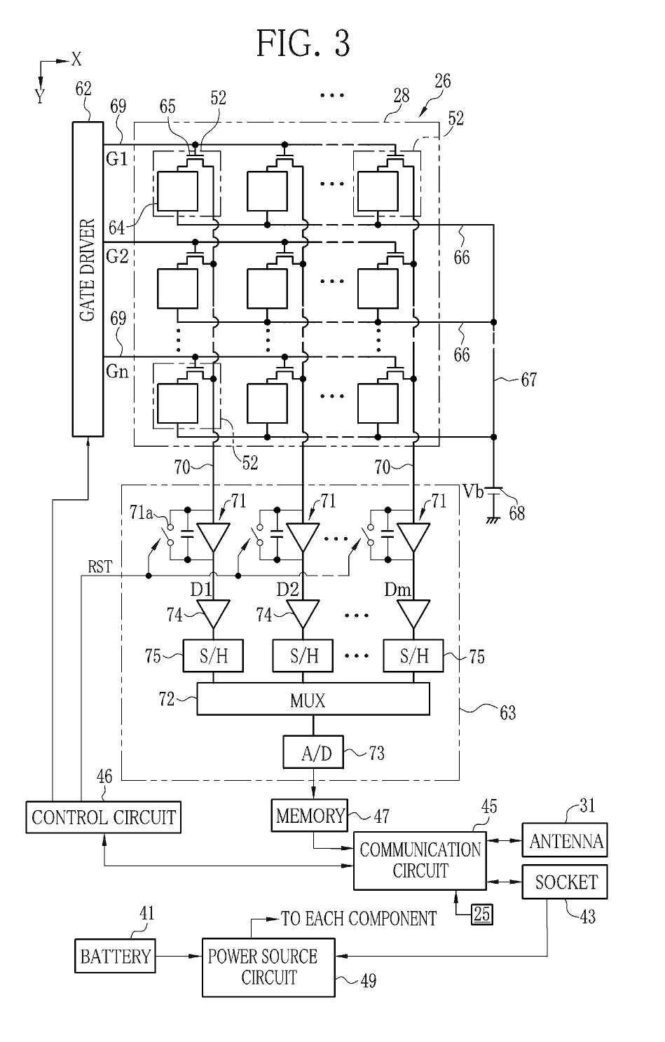

The X-ray imaging apparatus 12 is constituted of an electronic cassette 21, an upright imaging support 22a, a horizontal imaging support 22b, an imaging control device 23, and a console 24. The electronic cassette 21 includes an irradiation detection sensor 25, an FPD 26 (see FIGS. 2 and 3), and a portable case 27 (see FIG. 2) for containing the FPD 26. The electronic cassette 21 receives the X-rays that have been emitted from the X-ray source 13 and transmitted through a body part of a patient H, and outputs an X-ray image. The electronic cassette 21 is approximately rectangular and flat in shape, and has approximately the same size as those of a film cassette, an IP cassette, and a CR cassette. In other words, the electronic cassette 21 is compatible with International Standard ISO4090:2001 in size and shape.

The irradiation detection sensor 25 is disposed in the vicinity of an imaging surface 28 (see FIG. 3) of the FPD 26. The irradiation detection sensor 25 detects X-ray irradiation, and outputs an irradiation detection signal. The irradiation detection signal is inputted to the imaging control device 23 through a composite cable 29 or by radio. When the irradiation detection signal exceeds a predetermined value, the imaging control device 23 detects a start of X-ray irradiation by the X-ray source 13.

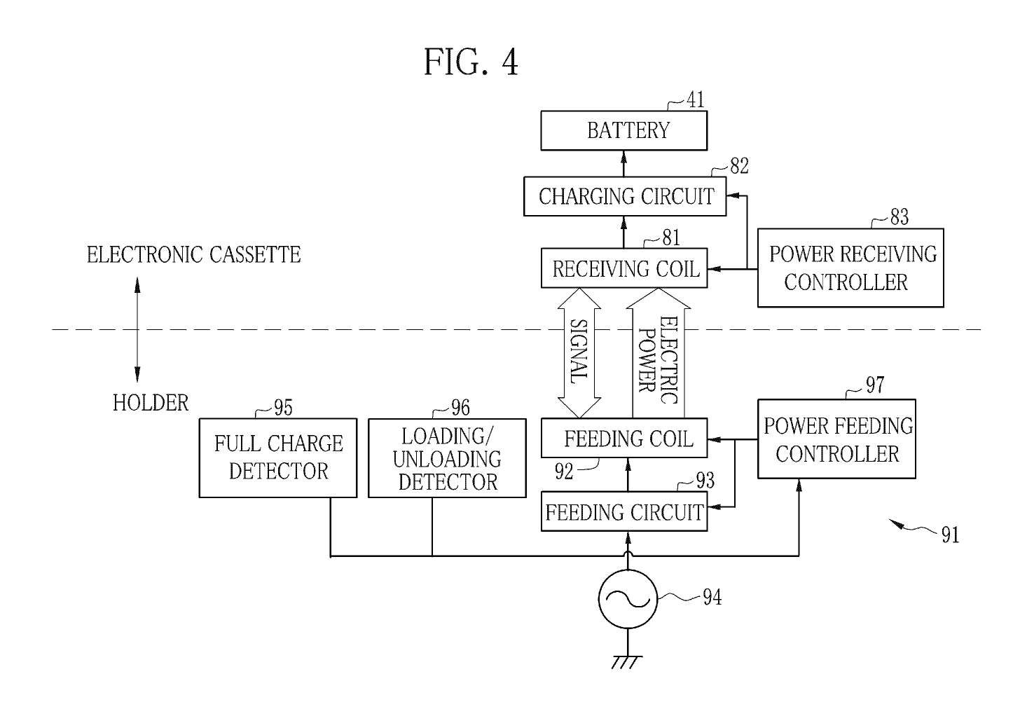

The upright imaging support 22a and the horizontal imaging support 22b have holders 30a and 30b, respectively, each of which has a power feeding device 91 (see FIG. 4), as described later. A cassette chamber CH1 is formed in the holder 30a, and a cassette chamber CH2 is formed in the holder 30b. The electronic cassette 21 is detachably loaded into the cassette chamber CH1 or CH2, and held in such a position that the imaging surface 28 being an X-ray incident surface is opposed to the X-ray source 13. FIG. 1 shows a state of taking a radiograph with the upright imaging support 22a. The X-ray source 13 is movable within a predetermined area in an examination room by a moving mechanism (not shown) such as a rail that is laid out on a ceiling of the examination room. In the case of using the horizontal imaging support 22b, the X-ray source 13 is moved to an upper portion of the horizontal imaging support 22b.

The case 27 of the electronic cassette 21 is approximately the same size as those of the film cassette, the IP cassette, and the CR cassette. Thus, not only the electronic cassette 21, but also the film cassette, the IP cassette, or the CR cassette can be loaded in the cassette chamber CH1 or CH2 of the imaging support 22a or 22b. A plural number of electronic cassettes 21 may be provided in the single examination room, and the two imaging supports 22a and 22b may be loaded with the separate electronic cassettes 21. In addition, the electronic cassette 21 is sometimes put on a bed where the patient H lies down or held by the patient H himself/herself for use alone.

The imaging control device 23 is connected to the electronic cassette 21 through the composite cable 29 or by radio via an antenna 31 (see FIG. 2), to control the electronic cassette 21. To be more specific, the imaging control device 23 sends the image capturing conditions to the electronic cassette 21 to set up signal processing conditions (gain of amplifiers 74 and the like) of the FPD 26, and indirectly controls the operation of the FPD 26. Also, the imaging control device 23 sends image data from the electronic cassette 21 to the console 24.

The imaging control device 23 has a CPU 23a for centralized control of the device 23, a communication section 23b, and a memory 23c. The communication section 23b establishes communication with the electronic cassette 21 in a wired or wireless method, and also establishes communication with the console 24 through a communication cable 32. The communication section 23b and the memory 23c are connected to the CPU 23a. The memory 23c stores control programs to be executed by the CPU 23a.

The console 24 sends the image capturing conditions to the imaging control device 23. Also, the console 24 applies various types of image processing such as offset correction and gain correction to X-ray image data sent from the imaging control device 23. The X-ray image after being subjected to the image processing is not only displayed on a monitor 24a of the console 24, but also written to a data storage device such as an image storage server connected to the console 24 over a network.

The console 24 accepts input of an examination order including patient information such as sex, age, the body part to be examined, and an examination purpose from a keyboard 24c, and displays the examination order on the monitor 24a. The examination order is inputted manually by the doctor or the radiologic technologist, or from an external system such as HIS (hospital information system) and RIS (radiography information system), which manage the patient information and radiographic examination information. The doctor or the radiologic technologist checks the contents of the examination order on the monitor 24a, and inputs the image capturing conditions from the keyboard 24c on an operation screen of the monitor 24a in accordance with the contents of the examination order.

As shown in FIGS. 2 and 3, the electronic cassette 21 contains the antenna 31 and a battery 41, to enable wireless communication with the imaging control device 23. The battery 41 supplies electric power of a predetermined voltage to each part of the electronic cassette 21 through a power source circuit 49. The battery 41 is relatively small in size enough to be contained in the slim electronic cassette 21. The battery 41 can be charged with the electric power from the power feeding device 91 (see FIG. 4) built into the holder 30a, 30b of each imaging support 22a, 22b. The battery 41 can be pulled out from the electronic cassette 21 through an openable lid 42 provided on one side of the electronic cassette 21, to be charged with a specific cradle. The antenna 31 sends and receives radio waves to and from the imaging control device 23 to establish the wireless communication.

The electronic cassette 21 is provided with a socket 43 in addition to the antenna 31. The socket 43 is disposed on one side of the electronic cassette 21 opposite to the lid 42. The socket 43 is used to establish wired communication with the imaging control device 23. Into the socket 43, a connector 44 of the composite cable 29 connected to the imaging control device 23 is inserted. The composite cable 29 is used in a case where the wireless communication between the electronic cassette 21 and the imaging control device 23 becomes unworkable due to low charge of the battery 41. In the case of using the composite cable 29 by insertion of the connector 44 into the socket 43, the electronic cassette 21 can establish the wired communication with the imaging control device 23, and the battery 41 can be recharged by the imaging control device 23.

The antenna 31 and the socket 43 are connected to a communication circuit 45. The communication circuit 45 mediates transmission of various types of information and signals including the image data among the antenna 31 or the socket 43, a control circuit 46, and a memory 47. Also, the electric power supplied through the socket 43 is fed to each part of the electronic cassette 21 through the power source circuit 49.

The FPD 26 has the imaging surface 28, which has a TFT active matrix substrate and plural pixels 52 arranged on the TFT active matrix substrate. Each pixel 52 accumulates signal charge by an amount corresponding to an amount of the X-rays incident thereon. The plural pixels 52 are arranged into a two-dimensional matrix with n rows (X direction) and m columns (Y direction) at a predetermined pitch.

The FPD 26 is of an indirect conversion type, having a scintillator (phosphor) for converting the X-rays into visible light. The pixels 52 perform photoelectric conversion of the visible light produced by the scintillator. The scintillator is made of CsI (cesium iodide), GOS (gadolinium oxysulfide), or the like, and is opposed to the entire imaging surface 28 having the matrix of the pixels 52. Note that, a direct conversion type FPD, which has a conversion layer (amorphous selenium or the like) for directly converting the X-rays into electric charge, may be used instead.

The pixel 52 includes a photodiode 64, a capacitor (not shown), and a thin film transistor (TFT) 65. The photodiode 64 being a photoelectric conversion element produces electric charge (electron and hole pairs) upon entry of the visible light. The capacitor accumulates the electric charge produced by the photodiode 64. The TFT 65 functions as a switching element.

The photodiode 64 is composed of a semiconducting layer (of a PIN type, for example) for producing the electric charge, and upper and lower electrodes disposed on the top and bottom of the semiconducting layer. The lower electrode of the photodiode 64 is connected to the TFT 65. The upper electrode of the photodiode 64 is connected to a bias line 66. The number of the bias lines 66 coincides with the number of rows (n rows) of the pixels 52. All the n bias lines 66 are connected to a bus line 67 that is connected to a bias power source 68. The bias power source 68 applies a bias voltage Vb to the upper electrodes of the photodiodes 64 through the bus line 67 and the bias lines 66. Since the application of the bias voltage Vb produces an electric field in the semiconducting layer, the electric charge (electron and hole pairs) produced in the semiconducting layer by the photoelectric conversion is attracted to the upper and lower electrodes, one of which has positive polarity and the other has negative polarity. Thereby, the electric charge is accumulated in the capacitor.

A gate electrode of the TFT 65 is connected to a scan line 69. A source electrode of the TFT 65 is connected to a signal line 70, and a drain electrode is connected to the photodiode 64. The scan lines 69 and the signal lines 70 are routed into a lattice. The number of the scan lines 69 coincides with the number of the rows (n rows) of the pixels 52. The number of the signal lines 70 coincides with the number of the columns (m columns) of the pixels 52. All the scan lines 69 are connected to a gate driver 62, and all the signal lines 70 are connected to a signal processing circuit 63.

The gate driver 62 drives the TFTs 65 to make the FPD 26 carry out an accumulation operation, a readout operation (real discharge operation), and a reset operation (idle discharge operation). In the accumulation operation, each pixel 52 accumulates the signal charge by an amount corresponding to the amount of the X-rays incident thereon. In the readout operation, the signal charge is read out from the pixels 52. The control circuit 46 controls start timing of each of the above operations carried out by the gate driver 62.

In the accumulation operation, while every TFT 65 is turned off, every pixel 52 accumulates the signal charge. In the readout operation, the gate driver 62 successively issues gate pulses G1 to Gn each of which drives the TFTs 65 of the same row at a time. Thereby, the scan lines 69 are activated one by one so as to turn on the TFTs 65 connected to the activated scan line 69 on a row-by-row basis. Upon turning on the TFT 65, the signal charge accumulated in the capacitor of the pixel 52 is read out to the signal line 70, and inputted to the signal processing circuit 63.

Dark charge occurs in the semiconducting layer of the photodiode 64 irrespective of the presence or absence of entry of the X-rays. Due to the application of the bias voltage Vb, the dark charge is accumulated in the capacitor. The dark charge occurring in the pixels 52 becomes noise of the image data, and therefore the reset operation is carried out to remove the dark charge. In other words, the reset operation is an operation in which the dark charge occurring in the pixels 52 is discharged through the signal lines 70.

The reset operation adopts a sequential reset method, for example, by which the pixels 52 are reset on a row-by-row basis. In the sequential reset method, as in the case of the readout operation of the signal charge, the gate driver 62 successively issues the gate pulses G1 to Gn to the scan lines 69, to turn on the TFTs 65 of the pixels 52 on a row-by-row basis. While the TFT 65 is turned on, the dark charge flows from the pixel 52 through the signal line 70 into an integration amplifier 71. In the reset operation, in contrast to the readout operation, a multiplexer (MUX) 72 does not read out the electric charge accumulated in the integration amplifiers 71. In synchronization with the issue of each gate pulse G1 to Gn, the control circuit 46 outputs a reset pulse RST to reset the integration amplifiers 71.

Instead of the sequential reset method, a parallel reset method or an all pixels reset method may be used. In the parallel reset method, the plural rows of the pixels are grouped together, and sequential reset is carried out in each group, so as to concurrently discharge the dark charge from the rows of a number of the groups. In the all pixels reset method, the gate pulse is inputted to every row to concurrently discharge the dark charge from every pixel. Adoption of the parallel reset method and the all pixels reset method can reduce time required for the reset operation.

The signal processing circuit 63 is provided with the integration amplifiers 71, the MUX 72, an A/D converter 73, and the like. One integration amplifier 71 is connected to each signal line 70. The integration amplifier 71 includes an operational amplifier and a capacitor connected between input and output terminals of the operational amplifier. The signal line 70 is connected to one of two input terminals of the operational amplifier. The other input terminal of the operational amplifier is connected to a ground (GND). The integration amplifier 71 integrates the signal charge inputted from the signal line 70, and converts the signal charge into a voltage signal D1 to Dm, and outputs the voltage signal D1 to Dm. The output terminal of the integration amplifier 71 of every column is connected to the MUX 72 through the amplifier 74 and a sample holder (S/H) 75. An output of the MUX 72 is connected to the A/D converter 73.

The MUX 72 successively chooses one of the plural integration amplifiers 71 connected in parallel, and inputs the voltage signal D1 to Dm outputted from the chosen integration amplifier 71 to the A/D converter 73 in series. The A/D converter 73 converts the inputted voltage signals D1 to Dm into digital data, and outputs the digital data to the memory 47 built into the case 27 of the electronic cassette 21. Note that, another amplifier may be provided between the MUX 72 and the A/D converter 73.

After the MUX 72 reads out from the integration amplifiers 71 the voltage signals D1 to Dm of one row, the control circuit 46 outputs the reset pulse RST to the integration amplifiers 71 to turn on reset switches 71a of the integration amplifiers 71. Thus, the signal charge of one row accumulated in the integration amplifiers 71 is reset. Upon the reset of the integration amplifiers 71, the gate driver 62 outputs the gate pulse of the next row to start reading out the signal charge from the pixels 52 of the next row. Successively repeating this operation, the signal charge is read out from the pixels 52 of every row.

After completion of the readout from every row, the image data representing the X-ray image of one frame is written to the memory 47. This image data is read out from the memory 47, and outputted to the imaging control device 23 through the communication circuit 45. Thereby, the electronic cassette 21 detects the X-ray image of the body part of the patient H.

In the FPD 26, the irradiation detection sensor 25 detects a start of X-ray irradiation, while the reset operation is repeatedly carried out. When the irradiation detection sensor 25 detects the start of X-ray irradiation, the control circuit 46 switches the operation of the FPD 26 from the reset operation to the accumulation operation. The control circuit 46 measures time elapsed from the start of the accumulation operation using a timer. When the measured time reaches time set by the image capturing conditions, the control circuit 46 switches the operation of the FPD 26 from the accumulation operation to the readout operation. In another case, without using the timer, when the irradiation detection sensor 25 detects an end of X-ray irradiation, the operation of the FPD 26 may be switched from the accumulation operation to the readout operation.

For a period of time between sending out the image data of one patient to the imaging control device 23 after the completion of taking radiographs of the patient and a start of taking radiographs of the next patient, the electronic cassette 21 is put into a sleep mode in which only minimum components including the communication circuit 45 and a charging circuit 82 (see FIG. 4) are energized, while energization of the other components is stopped to reduce power consumption. In response to acceptance of the image capturing conditions from the X-ray imaging apparatus 12, the electronic cassette 21 starts energizing the components other than the communication circuit 45 and the charging circuit 82 again, so the FPD 26 is put from the sleep mode into a ready mode in which the FPD 26 stands ready to take the X-ray image. In the ready mode, the FPD 26 waits for the detection of the start of X-ray irradiation, while repeating the reset operation.

As shown in FIG. 4, the electronic cassette 21 is provided with a receiving coil 81. The receiving coil 81 is connected to the charging circuit 82. The charging circuit 82, including an AC/DC converter (rectifier) and a DC regulator, converts AC power received by the receiving coil 81 into DC power, and outputs a voltage suitable for charging the battery 41. A power receiving controller 83 controls operation of the receiving coil 81 and the charging circuit 82. Note that, the electronic cassette 21 of the present invention is energized through the socket 43 during use of the socket 43. The use of the socket 43 does not require the provision of the battery 41. For this reason, the present invention is beneficial in the case of the wireless communication through the antenna 31. The present invention is also beneficial to an electronic cassette that does not have a power receiving function through the socket 43, as a matter of course.

The power feeding device 91 is built into the holder 30a, 30b of each imaging support 22a, 22b. The power feeding device 91 has a feeding coil 92. The feeding coil 92 is connected to an AC source 94 through a feeding circuit 93 including a rectifier and the like. The feeding coil 92 is opposed to the receiving coil 81 provided in the electronic cassette 21 at a distance of the order of several mm from the receiving coil 81, in a state that the electronic cassette 21 is set on the holder 30a or 30b. The feeding coil 92 feeds electric power to the receiving coil 81 in a noncontact manner by an electromagnetic induction method.

The holder 30a, 30b is provided with a full charge detector 95 and a loading/unloading detector 96. The full charge detector 95 detects whether or not the battery 41 is full. The loading/unloading detector 96 detects whether or not a cassette of any type is loaded in the cassette chamber CH1, CH2. The detectors 95 and 96 output their detection results to a power feeding controller 97. The power feeding controller 97 controls operation of the feeding coil 92 and the feeding circuit 93 in accordance with the detection results of the detectors 95 and 96.

To be more specific, in a case where the full charge detector 95 detects full charge of the battery 41, or a case where the loading/unloading detector 96 detects unloading of the cassette from the holder 30a, 30b, a noncontact power feeding operation is interrupted by cutting the connection between the feeding coil 92 and the AC source 94, or by stopping a drive of the AC source 94. Also, the noncontact power feeding operation is interrupted for a period of time between the taking of the radiographs upon the detection of the start of X-ray irradiation by the irradiation detection sensor 25 and the putting into the sleep mode after the completion of the transmission of the image data. The power feeding controller 97 performs the noncontact power feeding operation using the feeding coil 92 only for a period of time during the sleep mode in which no radiography and no image transmission is carried out, and for a duration of time between the entering into the ready mode and the detecting of the start of X-ray irradiation by the irradiation detection sensor 25.

As a method for detecting the full charge of the battery 41 by the power feeding device 91, the electronic cassette 21 may be provided with a device that monitors a discharge voltage and the like of the battery 41 to measure remaining battery charge. A measurement result may be sent from the electronic cassette 21 to the power feeding device 91 using the wired or wireless communication. As another method, the power feeding device 91 may measure an electric current passing through the feeding coil 92 and the AC source 94, and whether or not the battery 41 is fully charged is judged based on a measurement result. Any of the above methods is adoptable.

As a method for detecting the loading of the cassette in the holder 30a, 30b, for example, the holder 30a, 30b may be provided with a sensor (reflective light sensor, an ultrasonic sensor, a micro switch, an electromagnetic sensor, or the like) for detecting the loading and unloading of the cassette in an optical, mechanical, or electrical manner, and an output from the sensor is sent to the power feeding device 91 through the medium of the imaging control device 23 or the console 24. In another method, a specific circuit made of discrete (single-function) semiconductor may be provided as the loading/unloading detector 96, and an output of the specific circuit may be directly sent to the power feeding device 91.

Whether or not the irradiation detection sensor 25 has detected the start of X-ray irradiation and whether or not the image data is under transmission are inputted from the imaging control device 23 to the power feeding controller 97 of the power feeding device 91 using the wired or wireless communication. In another case, just as with a query signal and a response signal described later, the receiving coil 81 and the feeding coil 92 may transmit signals that indicate whether or not the irradiation detection sensor 25 has detected the start of X-ray irradiation and whether or not the image data is under transmission. In response to reception of these signals, the power feeding controller 97 interrupts the power feeding operation for a period of time between the detection of the start of X-ray irradiation by the irradiation detection sensor 25 and the entering into the sleep mode after the completion of the radiography and the image data transmission, as described above.

The power feeding device 91 is turned on in synchronization with turn-on of the imaging control device 23. In another case, the power feeding device 91 may be manually turned on by operation of a power switch or the like. After the turning-on of the power feeding device 91, upon receiving from the loading/unloading detector 96 the signal indicating the loading of the cassette in the holder 30a, 30b, the power feeding controller 97 controls the operation of the feeding circuit 93 so as to intermittently pass a feeble current through the feeding coil 92. The intermittent passage of the feeble current through the feeding coil 92 produces a weak magnetic field. This magnetic field is used for finding out whether or not the cassette loaded in the holder 30a or 30b has the power receiving function. This magnetic field is called query signal in description below.

In a case where the electronic cassette 21 having the power receiving function is loaded in the holder 30a, 30b, the receiving coil 81 receives the query signal. The power receiving controller 83 passes a feeble current through the receiving coil 81 during a pause of issue of the query signal to produce a weak magnetic field. This is transmitted to the feeding coil 92 as a response signal answering the query signal. Upon reception of the response signal by the feeding coil 92, the power feeding controller 97 stops issuing the query signal, which has been periodically carried out. By the reception of the response signal, the power feeding controller 97 recognizes that the cassette loaded in the holder 30a, 30b is the electronic cassette 21 having the power receiving function, and starts the noncontact power feeding operation through the feeding coil 92. The receiving coil 81 and the feeding coil 92 are used as transceivers of the query signal and the response signal, in addition to receiving and feeding sections for charging power of the battery 41.

On the other hand, in a case where an electronic cassette without having the power receiving function or a film cassette, an IP cassette, or a CR cassette without having the power receiving function is loaded in the holder 30a, 30b, the cassette cannot send out the response signal answering the query signal, as a matter of course. The same goes for a case where the electronic cassette 21 cannot send out the response signal due to a failure of the receiving coil 81 and the like. In such cases, if the feeding coil 92 keeps on sending the query signal, the query signal becomes noise causing image quality deterioration.

For this reason, the power feeding controller 97 actuates a built-in timer upon a start of issuing the query signal. If no response signal is received for a predetermined time (15 seconds, for example), the power feeding controller 97 judges that no electronic cassette exists, and stops issuing the query signal. In another case, the power feeding controller 97 may count the number of issue of the periodic query signal. If no response signal is received while the query signal is issued for a predetermined number of times, the power feeding controller 97 may stop issuing the query signal. In a case where the loading/unloading detector 96 has detected the unloading of the cassette from the holder 30a, 30b, the power feeding controller 97 issues no query signal, until the loading/unloading detector 96 detects that some cassette is loaded again in the holder 30a, 30b.

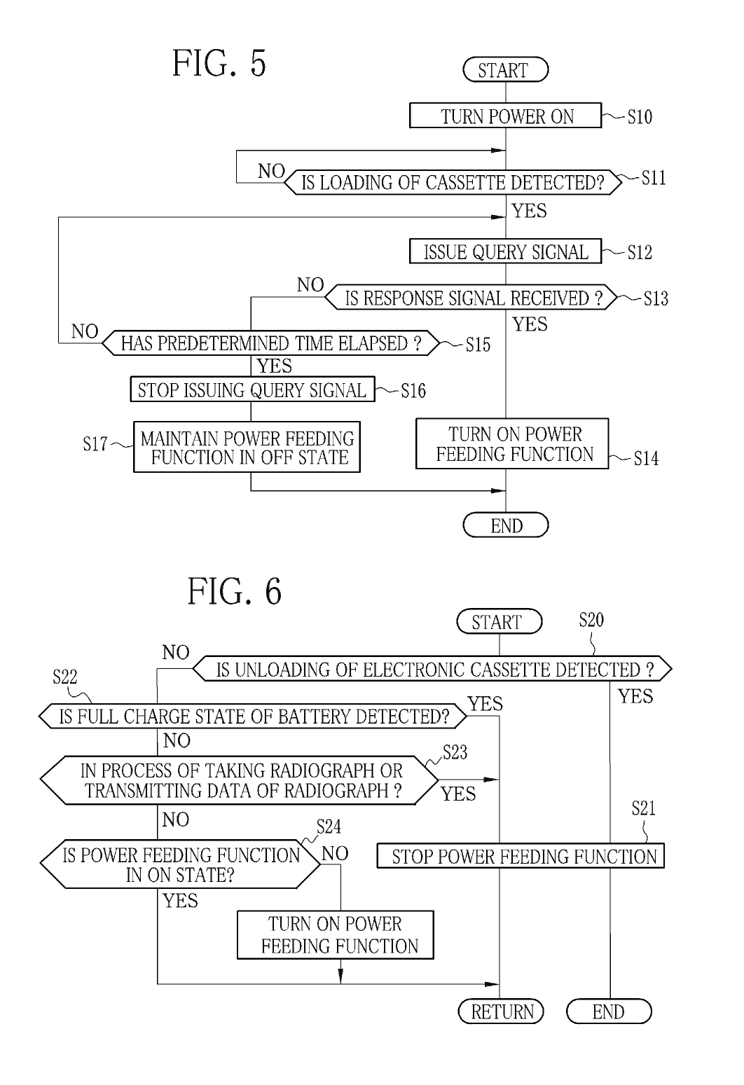

The operation of the above structure will be described with referring to flowcharts of FIGS. 5 and 6. In taking the radiograph with the X-ray image capturing system 10, one of the upright and horizontal imaging supports 22a and 22b, for example, the upright imaging support 22a is chosen in accordance with the patient's body part to be examined. The electronic cassette 21 is loaded in the chosen imaging support 22a. After that, the height of the electronic cassette 21 is adjusted in accordance with the height of the patient H such that the electronic cassette 21 is opposed to the body part. The height of the X-ray source 13 and the size of the irradiation field are adjusted in accordance with the height of the electronic cassette 21 and the size of the body part.

In turning on the electronic cassette 21, the electronic cassette 21 starts up in the sleep mode. Subsequently, the X-ray imaging apparatus 12 is turned on as shown in S10 of FIG. 5, and then the image capturing conditions are inputted to the console 24. The imaging control device 23 sets the image capturing conditions to the electronic cassette 21. The electronic cassette 21 is switched from the sleep mode to the ready mode. The image capturing conditions are also set to the source controller 14.

The power feeding controller 97 of the power feeding device 91 monitors the detection result of the loading/unloading detector 96 after the turn-on of the X-ray imaging apparatus 12. When the signal indicating that some cassette is being loaded in the holder 30a is inputted from the loading/unloading detector 96 (YES in S11), the query signal is sent from the feeding coil 92 under control of the power feeding controller 97 (S12). Note that, the electronic cassette 21 is sometimes loaded in the imaging support 22a, after the position adjustment of the imaging support 22a and the turn-on of the X-ray imaging apparatus 12. In this case, the query signal is issued, when the electronic cassette 21 being turned on is loaded in the imaging support 22a.

In a case where the electronic cassette 21 having the power receiving function is loaded in the holder 30a, the receiving coil 81 receives the query signal. Thereafter, the receiving coil 81 issues the response signal answering the query signal under control of the power receiving controller 83. The feeding coil 92 receives the response signal (YES in S13), so the power feeding device 91 starts the noncontact power feeding operation from the feeding coil 92 to the receiving coil 81 in the electromagnetic induction method (S14).

On the other hand, in a case where the cassette having no power receiving function (the electronic cassette, the IP cassette, the film cassette, the CR cassette, and the like without having the power receiving function) is loaded in the holder 30a, the cassette cannot respond to the query signal. In a case where no response signal is received for the predetermined time after the start of issuing the query signal (NO in S13 and YES in S15), the power feeding controller 97 stops issuing the query signal (S16). In this case, the noncontact power feeding function using the feeding coil 92 is not actuated (S17).

After a preparation for radiography is completed, the doctor or the radiologic technologist half presses the exposure switch 15. Thus, the warm-up start signal is sent to the source controller 14 to start warming up the X-ray source 13. After a lapse of predetermined time, the exposure switch 15 is fully pressed, so the irradiation start signal is sent to the source controller 14 to start the X-ray irradiation.

While the FPD 26 carries out the reset operation, the irradiation detection sensor 25 detects the start of X-ray irradiation. When the start of X-ray irradiation has been detected, the control circuit 46 turns off every TFT 65, and switches to the accumulation operation. The source controller 14 stops the X-ray irradiation after a lapse of irradiation time set in the image capturing conditions. Also, the FPD 26 switches from the accumulation operation to the readout operation after a lapse of predetermined time corresponding to the irradiation time set in the image capturing conditions. In the readout operation, the signal charge accumulated in the pixels 52 is successively read out from row to row, and the read signal charge is recorded to the memory 47 as the X-ray image data of the single frame. This image data is transmitted to the console 24 through the imaging control device 23.

The image data is subjected to the various types of image processing including the offset correction, the gain correction, and the like in the console 24. After that, the image data is displayed on the monitor 24a of the console 24, and stored on the data storage device. This sequential operation is repeated until the completion of taking all the photographs scheduled.

In an electronic cassette searching operation of FIG. 5, in a case where it is judged that the electronic cassette 21 has the power receiving function, the electronic cassette 21 becomes in a used state. In the used state, as shown in FIG. 6, the feeding coil 92 charges power to the battery 41. After taking the radiographs, the electronic cassette 21 is unloaded from the holder 30a of the imaging support 22a. In a case where the loading/unloading detector 96 detects the unloading of the electronic cassette 21 (YES in S20), the noncontact power feeding function using the feeding coil 92 is interrupted (S21). In this case, the use of the electronic cassette 21 is completed.

On the other hand, in a case where the electronic cassette 21 in the used state is still loaded in the holder 30a (NO in S20), the full charge detector 95 checks whether or not the battery 41 is in a full charge state. If the battery 41 is in the full charge state (YES in S22), the power feeding function is stopped (S21), and the operation returns to start. If the battery 41 is not in the full charge state (NO in S22), a present state of the electronic cassette 21, that is, whether or not the electronic cassette 21 is in the process of taking the radiograph or transmitting the X-ray image data is judged. If the electronic cassette 21 is in the process of taking the radiograph or transmitting the X-ray image data (YES in S23), the power feeding function is stopped (S21), and the operation returns to the start. If the electronic cassette 21 is not in the process of taking the radiograph or transmitting the X-ray image data (NO in S23), whether or not the power feeding function is in an on-state is judged (S24). In a case where the power feeding function is in the on-state (YES in S24), the operation returns to the start while the power feeding function remains in the on-state. In a case where the power feeding function is in an off-state (NO in S24), the operation returns to the start after turning on the power feeding function.

According to the present invention, as described above, the query signal, which is issued by the power feeding device 91 to find out the electronic cassette 21 having the power receiving function, is stopped after the lapse of predetermined time. Therefore, in a case where the cassette without having the power receiving function is loaded in the holder 30a or 30b for use, it is possible to prevent the occurrence of noise of the image data caused by the continuous issue of the query signal, and hence certainly prevent deterioration in image quality.

The issue of the query signal is started when the loading/unloading detector 96 has detected that the cassette is loaded in the holder 30a or 30b, and the issue of the query signal is automatically stopped, if no response signal is received for the predetermined time. This obviates the necessity for the doctor or the radiological technologist to manually stop the query signal in accordance with the type of the cassette. The doctor or the radiological technologist can carry out radiography without paying attention to the type of the cassette, in other words, whether or not the cassette has the power receiving function.

The operation of the power feeding device 91 is stopped for the period of time between the taking of the radiographs upon the detection of the start of X-ray irradiation by the irradiation detection sensor 25 and the entering into the sleep mode after the completion of the image data transmission. Therefore, it is possible to ensure electromagnetic compatibility (EMC) during a time of taking the radiographs and a time of transmitting the image data in which the noise tends to be superimposed on the image data.

In order to reduce radiation exposure of the patient H, the FPD 26 uses a sensitive detector enough to detect a feeble electromagnetic wave. Thus, it is highly necessary to ensure the EMC during the radiography and prevent deterioration in the image quality caused by electromagnetic noise. Therefore, the present invention is of great utility.

In the above embodiment, the power feeding is stopped, when the irradiation detection sensor 25 has detected the start of X-ray irradiation, and switching between charging and non-charging of the battery 41 is automatically carried out. However, a switch for commanding the charging and non-charging may be provided in one of each imaging support 22a, 22b, the power feeding device 91, the imaging control device 23, and the console 24. The noncontact power feeding operation may be started or stopped by the operation of the switch.

In the above embodiment, when the loading/unloading detector 96 detects the loading of the cassette in the holder 30a or 30b, the issue of the query signal is started. Instead of this or in addition to this, the issue of the query signal may be started when the cassette is turned on. Even if the cassette loaded in the holder 30a or 30b has the power receiving function, the cassette cannot receive the query signal unless the cassette is turned on. For this reason, both the detection of the cassette by the loading/unloading detector 96 and the turn-on of the cassette may trigger the start of issuing the query signal.

In another case, when the image capturing conditions are inputted from the console 24 and set to the electronic cassette 21 through the imaging control device 23, the issue of the query signal may be started. In short, the issue of the query signal may be started at any time, as long as the type of the cassette can be found out by the issue of the query signal, before the image capturing conditions are inputted from the console 24 and the radiography is started with the cassette loaded in the holder 30a or 30b. Note that, the turn-on of the cassette and the input of the image capturing conditions to the electronic cassette 21 are received by the power feeding controller 97 through the imaging control device 23 and the like, or transmitted between the receiving coil 81 and the feeding coil 92.

Instead of checking the loading of the cassette in the holders 30a and 30b of the imaging supports 22a and 22b, for example, a bed is marked with a power feedable area of the power feeding device 91. Whether or not the cassette is disposed inside the power feedable area is detected, and the same operation as above may be carried out.

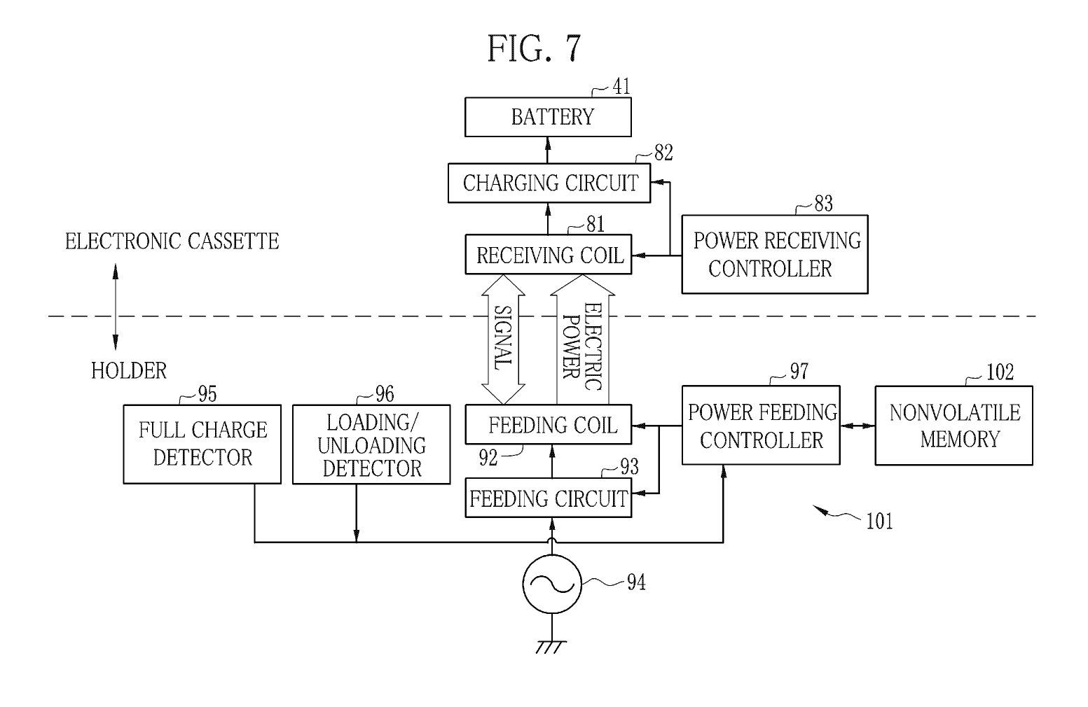

A power feeding device 101 shown in FIG. 7 is provided with a nonvolatile memory 102, which holds memory contents even after the power feeding device 101 is turned off. The nonvolatile memory 102 stores the distinction result of the type of the cassette (the presence or absence of reception of the response signal) in response to the query signal, i.e. information about whether or not the cassette has the power receiving function. Furthermore, the loading/unloading detector 96 is driven all the time by a power source different from that of the power feeding device 101, to monitor whether or not the cassette is replaced for a duration from turn-off of the power feeding device 101 to re-turn-on of the power feeding device 101. If the cassette is not replaced, the operation of the power feeding device 101 is controlled based on the memory contents of the nonvolatile memory 102, upon the re-turn-on of the power feeding device 101.

To be more specific, in a case where the cassette is not replaced for the duration from the turn-off of the power feeding device 101, and the memory contents of the nonvolatile memory 102 indicate that the cassette has the power receiving function, the noncontact power feeding operation using the feeding coil 92 is started immediately after the re-turn-on of the power feeding device 101. On the other hand, in a case where the cassette is not replaced for the duration from the turn-off of the power feeding device 101, and the memory contents indicate that the cassette does not have the power receiving function (the response signal has not been received), power feeding function is not started up upon the re-turn-on of the power feeding device 101. In a case where the cassette is replaced for the duration from the turn-off of the power feeding device 101 to the re-turn-on thereof, the issue of the query signal is started upon the re-turn-on, as in the case of the above embodiment. This eliminates the need for checking the type of the cassette whenever the power feeding device 101 is turned on.

The distinction result of the type of the cassette may be sent from the power feeding device to the imaging control device or the console. The imaging control device or the console may store and manage the distinction result of the type of the cassette in its volatile or nonvolatile memory. The console or the like may collectively manage the distinction results of the type of the cassettes that are set in the plural X-ray image capturing systems present in plural X-ray examination rooms.

The operation of the power feeding device may be stopped before the detection of the start of X-ray irradiation, for example, upon setting the image capturing conditions to the electronic cassette through the imaging control device. In another case, the setting of the patient in the imaging support (when the patient stands in front of the upright imaging support or lies down on the horizontal imaging support) is detected in an optical, mechanical, or electrical manner, and the operation of the power feeding device may be stopped upon the detection. This is suitable for a type of cassette without having the irradiation detection sensor.

In the above embodiments, the image data is transmitted immediately after taking the radiograph, but the transmission of the image data may be performed after a while, or the image data of several frames may be transmitted at a time after taking the several radiographs. In these cases, the power feeding device is actuated to charge the battery after taking the radiograph or radiographs, and the operation of the power feeding device is stopped again while transmitting the image data.

In the case of transmitting the image data in a communication method relatively resistant to the electromagnetic noise, the power feeding operation may be not necessarily stopped during the transmission of the image data.

In the above embodiment, the electromagnetic induction method is taken as an example of a method of the noncontact power feeding operation, but another noncontact power feeding method such as a magnetic resonance method using an LC resonance circuit, a microwave feeding method using an electromagnetic wave in a microwave band, an electric field coupling method in which the electric power is transmitted between two flat-plate electrodes, a laser feeding method, and an ultrasonic feeding method may be adopted instead. In the electromagnetic induction method and the magnetic resonance method, the feeding coil and the receiving coil are used as antennas for transmitting the query signal and the response signal, just as with the above embodiments. In the other methods, a well-known antenna including a plane antenna and a plate antenna is usable.

The X-ray image capturing system of the present invention is not necessarily of a stationary type installed in the X-ray examination room of a hospital, but may be of a type mounted in a car or portable. In the portable type of system, the X-ray source, the source controller, the electronic cassette, the imaging control device, and the like are brought to anywhere requiring emergency medical treatment such as an accident site and a natural disaster site, and to a private home of a home-care patient.

In the above embodiment, the system does not have the function of communicating between the X-ray generating apparatus and the X-ray imaging apparatus, but the present invention is applicable to a system with such function. In this case, the irradiation detection sensor, which detects the start of X-ray irradiation, becomes unnecessary. A synchronization signal indicating the start of X-ray irradiation is transmitted from the source controller to the imaging control device, and the power feeding function of the power feeding device is stopped in response to the synchronization signal.

In the above embodiment, the electronic cassette and the imaging control device are separated, but may be integrated into one unit, for example, by including the function of the imaging control device in the control circuit of the electronic cassette. The imaging control device, instead of the console, may carry out the image processing. Furthermore, the console and the imaging control device may be integrated into one unit. The present invention may be applicable to a general battery charging device.

The present invention is applicable to an image capturing system using any type of radiation, not only the X-rays but also γ-rays or the like.

Although the present invention has been fully described by the way of the preferred embodiment thereof with reference to the accompanying drawings, various changes and modifications will be apparent to those having skill in this field. Therefore, unless otherwise these changes and modifications depart from the scope of the present invention, they should be construed as included therein.

What is claimed is:

1. A power feeding device for an electronic cassette having a battery rechargeable by a noncontact power feeding operation, said power feeding device comprising:
a signal sending section for sending a query signal as a query operation to check whether or not a cassette being set in a predetermined position is said electronic cassette having a power receiving function;
a signal receiving section for receiving a response signal issued by said electronic cassette in response to said query signal; and
a control section for starting said query operation; for stopping said query operation, if no response signal is received for a predetermined time; and for enabling said noncontact power feeding operation to said battery, if said set cassette is judged to be said electronic cassette having said power receiving function by reception of said response signal.

2. The power feeding device according to claim 1, wherein if said cassette is set in said predetermined position, said cassette is loaded in a cassette chamber formed in an imaging support.

3. The power feeding device according to claim 2, wherein said signal sending section and said signal receiving section are provided in said imaging support.

4. The power feeding device according to claim 3, wherein each of said signal sending section and said signal receiving section includes an antenna for sending and receiving an electromagnetic wave.

5. The power feeding device according to claim 4, wherein
said signal sending section and said signal receiving section carryout said noncontact power feeding operation to said battery in addition to said query operation; and
a weak electromagnetic wave is used in said query operation, while a strong electromagnetic wave is used in said noncontact power feeding operation.

6. The power feeding device according to claim 3, further comprising a cassette detector for detecting loading of said cassette in said cassette chamber, wherein
upon said cassette detector detecting loading of said cassette, said control section starts said query operation.

7. The power feeding device according to claim 6, wherein upon turning on of said cassette, said control section starts said query operation.

8. The power feeding device according to claim 6, further comprising a nonvolatile memory for storing information about whether or not said electronic cassette has said power receiving function, said information being judged by presence or absence of reception of said response signal, wherein
said cassette detector is maintained in an energized state, even after said imaging support is turned off;
in a case where said cassette detector has detected replacement of said cassette during turn-off of said imaging support, said control section carries out said query operation, upon turning on of said imaging support; and
in a case where said cassette detector has not detected replacement of said cassette during turn-off of said imaging support, upon turn-on of said imaging support, said control section enables said noncontact power feeding operation if said cassette is said electronic cassette based on said information stored on said nonvolatile memory, without carrying out said query operation.

9. The power feeding device according to claim 8, wherein said nonvolatile memory is provided in an imaging control device, and said imaging control device is connected to said imaging support and controls operation of said electronic cassette.

10. The power feeding device according to claim 3, wherein said control section stops said noncontact power feeding operation, while said electronic cassette is in process of taking a radiograph or transmitting data of said radiograph.

11. The power feeding device according to claim 3, wherein said control section stops said noncontact power feeding operation, if said battery is in a full charge state or said electronic cassette is unloaded from said cassette chamber.
